(19) United States
(12) Patent Application Publication
(10) Pub. No.: US 2016/0178662 A1
(43) Pub. Date: Jun. 23, 2016

(54) TESTING APPARATUS HAVING TEST BASE WITH DETACHABLE SUPPORT PLATE

(71) Applicants: Fu Tai Hua Industry (Shenzhen) Co., Ltd., Shenzhen (CN); HON HAI PRECISION INDUSTRY CO., LTD., New Taipei (TW)

(72) Inventors: JU-LAN HAO, Shenzhen (CN); LI-JUN LI, Shenzhen (CN)

(21) Appl. No.: 14/587,691

(22) Filed: Dec. 31, 2014

(30) Foreign Application Priority Data
Dec. 22, 2014 (CN) 201410809735.9

(51) Int. Cl. G01R 1/04; G01R 1/073

(52) U.S. Cl. CPC G01R 1/0408; G01R 1/073

(57) ABSTRACT

A testing apparatus includes a test base, a support plate configured for supporting a device located on the test base, and a testing module located on the test base configured for testing the device. The support plate is detachably coupled with the test base.

### FIELD

The subject matter herein generally relates to a testing apparatus having a support plate formed detachably with a test base.

### BACKGROUND

A typical testing apparatus is configured for testing performance of products. However, a typical testing apparatus is designed to be configured for testing only one type of electric devices. When another different types of device need tested, the entire testing apparatus needs be designed according to the different devices.

### BRIEF DESCRIPTION OF THE DRAWINGS

Implementations of the present technology will now be described, by way of example only, with reference to the attached figures.

FIG. 1 illustrates a testing apparatus configured for testing an electric device M in accordance with a first embodiment of the present disclosure.

FIG. 2 is an exploded view of the testing apparatus of FIG. 1.

FIG. 3 is an isometric view showing a coupling module of the testing apparatus of FIG. 1 coupled to a connecting module of the testing apparatus of FIG. 1.

FIG. 4 is an isometric view showing a coupling module of the testing apparatus of FIG. 1 decoupling with a connecting module of the testing apparatus of FIG. 1

FIG. 5 is an exploded view of a testing apparatus in accordance with a second embodiment of the present disclosure.

FIG. 6 shows a support plate of the testing apparatus of FIG. 5 assembling with a test base of the testing apparatus of FIG. 5.

FIG. 7 is an exploded view of a testing apparatus in accordance with a third embodiment of the present disclosure.

FIG. 8 is an assembled view of the testing apparatus of FIG. 7.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

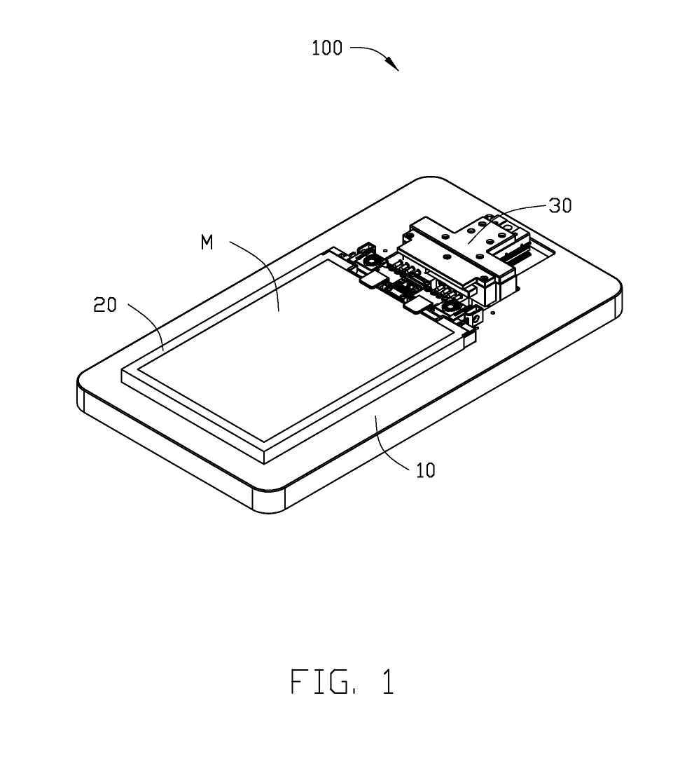

FIG. 1 illustrates a testing apparatus 100 in accordance with a first embodiment of the present disclosure. The testing apparatus 100 includes a test base 10, a support plate 20 located on the test base 10, and a testing module 30 located on the test base 10. The support plate 20 is configured for supporting an electric device M. The testing module 30 is configured for testing performance of the electric device M. The support plate 20 detachably couples with the test base 10.

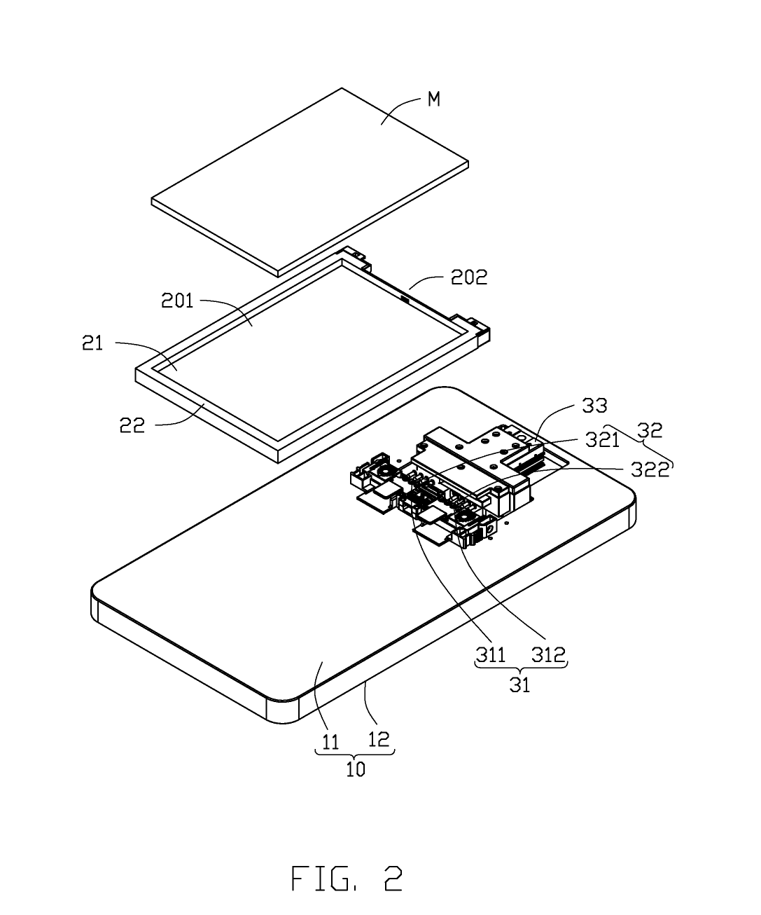

FIG. 2 illustrates the support plate 20 is dissembled from the test base 10. The test base 10 includes an upper face 11 and a bottom face 12 opposite to the upper face 11. The test base 10 can be made of rubber. In this embodiment, the test base 10 is rectangular.

The support plate 20 includes a bottom plate 21 and a side wall 22 extending from a periphery of the bottom plate 21. The bottom plate 21 and the side wall 22 corporately define a receiving space 201 for receiving the electric device M therein.

An opening 202 is defined at a side of the support plate 20. The testing module 30 can extends through the opening 202 to electrically couple with the electric device M. The support plate 20 can be directly arranged on the upper face 11 of the test base 10. The electric device M can be cell phone, notebook, or touch-pads and so on.

The testing module 30 is located on the upper face 11 of the test base 10. The testing module 30 can be arranged at a side of the upper face 11 near an edge of the upper face 11. The testing module 30 can be detachably coupled with the test base 10.

The testing module 30 includes a coupling module 31, a connecting module 32 configured for coupling with the coupling module 31, and an operation module 33 configured for operating the connecting module 32.

The coupling module 31 includes a first coupling part 311 and a second coupling part 312 spaced from the first coupling part 311. Front ends of the first coupling part 311 and the second coupling part 312 can be configured to electrically couple with the electric device M, and back ends of the first coupling part 311 and the second coupling part 312 are configured for electrically coupling with the connecting module 32.

The connecting module 32 includes a first coupling part 321 and a second coupling part 322. The first coupling part 321 and the second coupling part 322 correspond to the first coupling part 311 and the second coupling part 312 respectively. In at least one embodiment, the first coupling part 311 and the second coupling part 312 each includes a plurality of contact springs, and the first coupling part 321 and the second coupling part 322 each includes a plurality of contact probes.

The operation module 33 is located at a side of the connecting module 32 which is away from the support plate 20. The operation module 33 is configured to operate the connecting module 32 coupling with the coupling module 31 or decoupling with the coupling module 31.

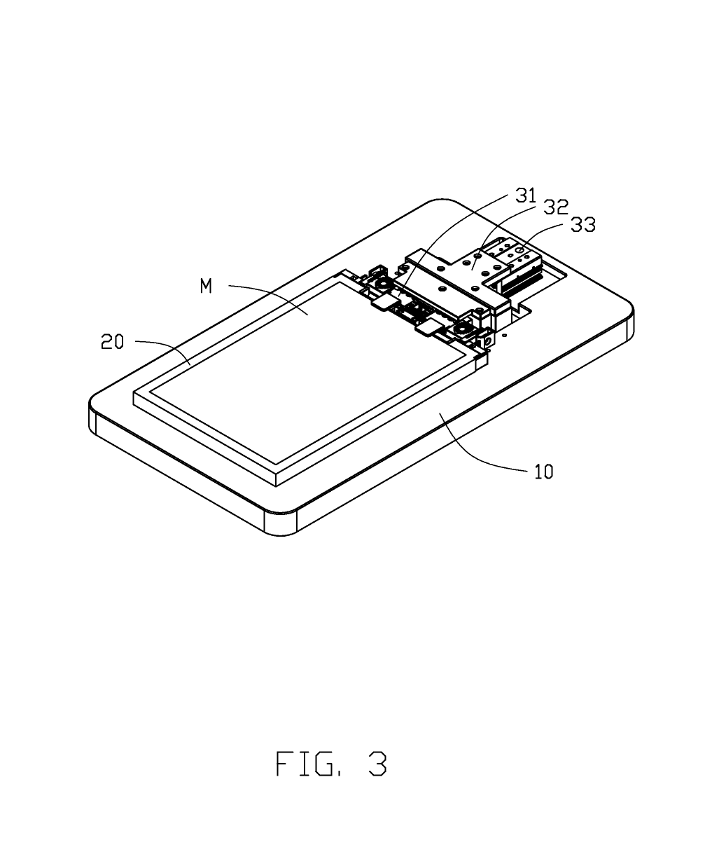

Referring to FIG. 3, when the operation module 33 operates the connecting module 32 towards the coupling module 31, the first coupling part 311 and the second coupling part 312 of the coupling module 31 electrically couples with the first coupling part 321 and the second coupling part 322 of the connecting module 32 respectively. The connecting module 32 electrically couples with the coupling module 31 to supply electricity power for the electric devices M to stand by for testing.

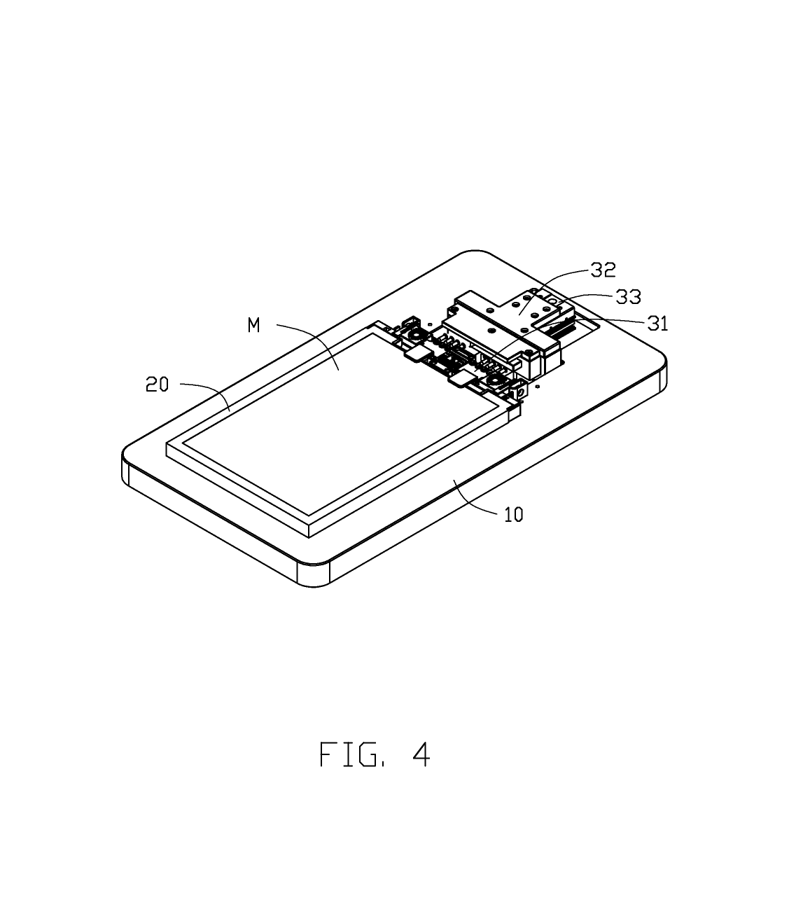

Referring to FIG. 4, when the operation module 33 operates the connecting module 32 to move away from the coupling module 31, the first coupling part 311 and the second coupling part 312 of the coupling module 31 electrically decouples with the first coupling part 321 and the second coupling part 322 of the connecting module 32 respectively. The connecting module 32 electrically decouples with the coupling module 31. In at least one embodiment, the operation module 33 can include an air cylinder.

In this embodiment, because the support plate 20 is detachably coupled with the test base 10, the support plate 20 can be designed according to different kinds of electric devices M individually instead of designing the entire testing apparatus 100, which decreases the cost of the testing apparatus 100.

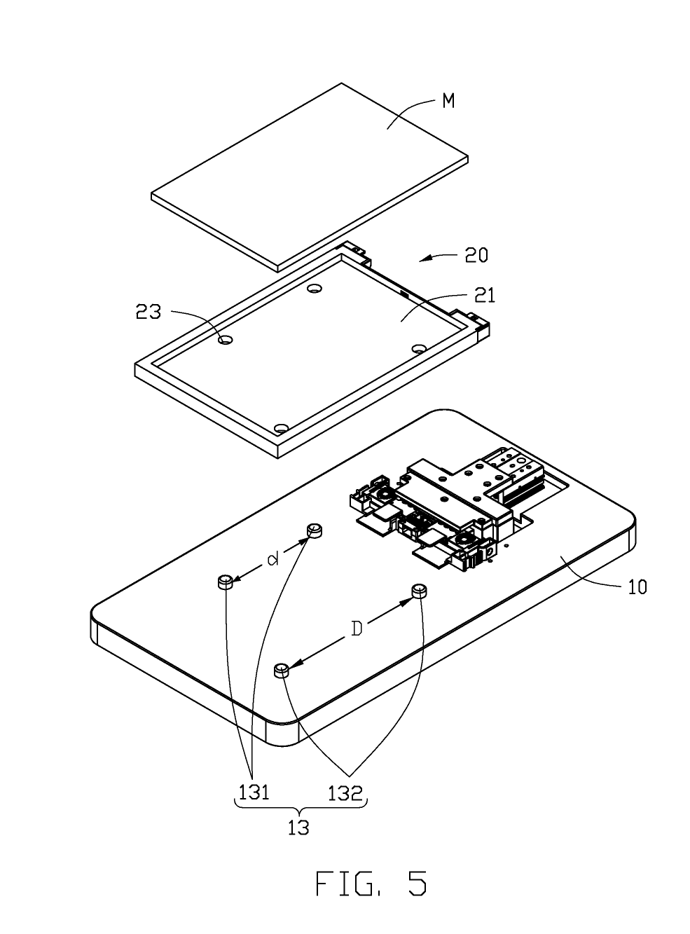

Referring to FIG. 5, the test base 10 has a location part 13, and the support plate 20 has a plurality of location holes 23. The location part 13 of the test base 10 can be received in the location holes 23 respectively to detachably combine the test base 10 and the support plate 20.

The location parts 13 upwardly extend from the upper face 11 of the test base 10. The location parts 13 can be cylindrical. Alternatively, the location parts 13 can be designed to be different configurations.

The location parts 13 include a plurality of first location parts 131 and a plurality of second location parts 132 spaced from the first location parts 131. The plurality of first location parts 131 are located at a side of the test base 10. The plurality of second location parts 132 are located at an opposite side of the test base 10. The first location parts 131 are aligned, and are arranged along a longitudinal direction of the test base 10. The plurality of second location parts 132 are aligned, and are arranged along a longitudinal direction of the test base 10. Preferably, a distance d between each two adjacent first location parts 131 is less than a distance D between each two adjacent second location parts 132. In this embodiment, the location part 13 has two first locations parts 131 and two second location parts 132.

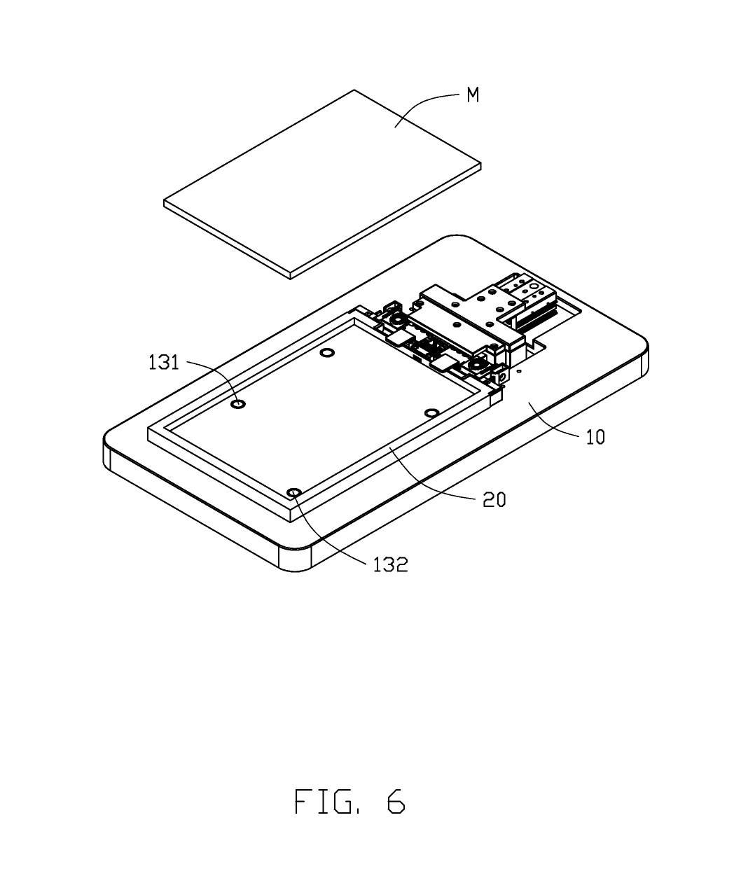

Referring to FIG. 6, the location holes 23 extend from a lower face of the bottom plate 21 towards an upper face of the bottom plate 21. The location holes 23 can extend through the bottom plate 21 of the support plate 20. A depth of each location hole 23 is larger or equal than a height of the location part 13.

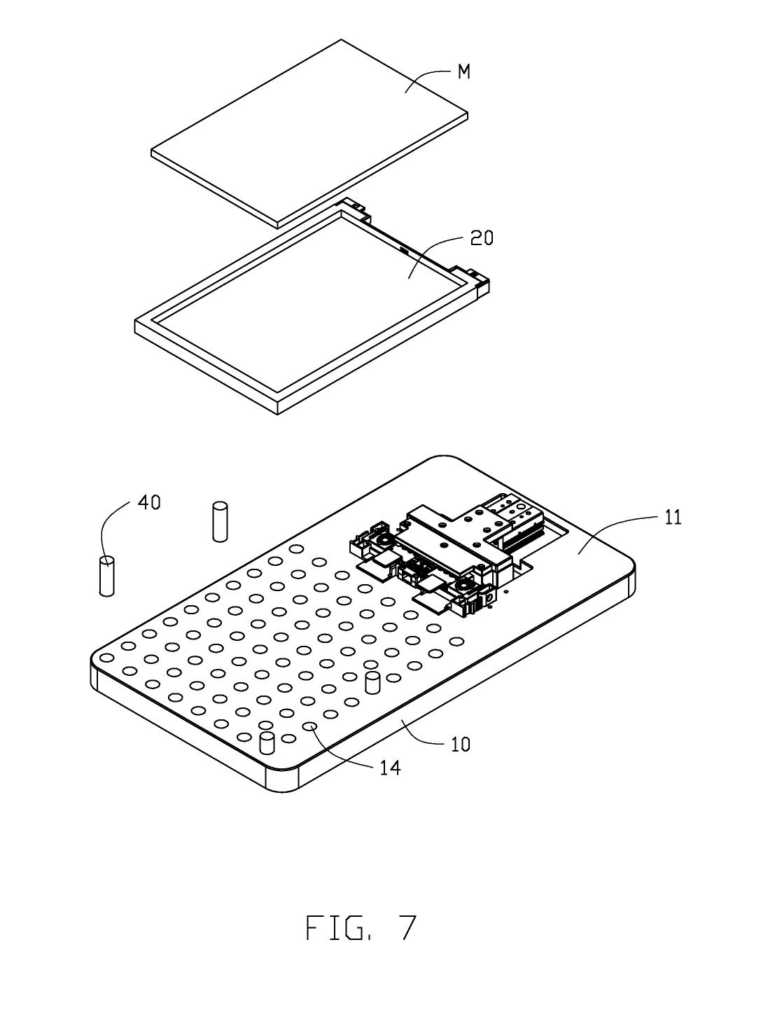

Referring to FIG. 7, the test base 10 has a plurality of receiving cavities 14 arranged in upper face 11. The receiving cavities 14 are evenly divided. The receiving cavities 14 can pass through the test base 10, or cannot pass through the test base 10. In this embodiment, the receiving cavities 14 do not pass through the test base 10.

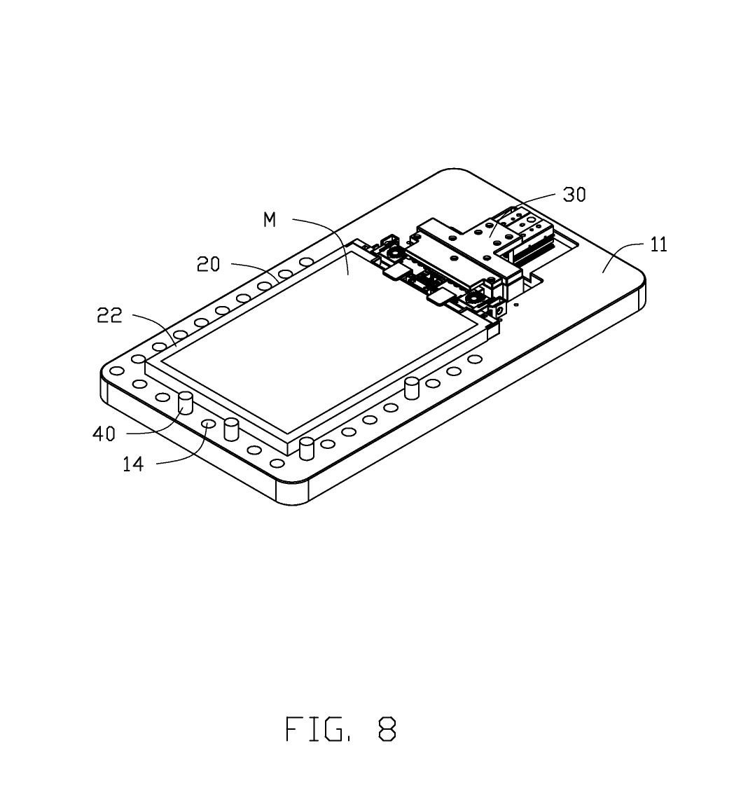

A plurality of fixing parts 40 are configured to match with the receiving cavities 14. A height of the fixing parts 40 is higher than a depth of the receiving cavities 14. Referring to FIG. 8, when an end of each of the fixing parts 40 inserts into each of the receiving cavities 14, the other end of each fixing parts 40 is exposed out of the receiving cavities 14. The exposed part of the fixing parts 40 is configured to locate the support plate 20. Preferably, the fixing parts 40 can be made of elastic materials.

In this embodiment, when the support plate 20 is placed on the upper face 11 of the test base 10, the fixing parts 40 can be inserted into the receiving cavities 14 located at a periphery of the support plate 20 to locate the support plate 20. In this embodiment, outer wall of the fixing parts 40 directly abuts peripheral sides of the support plate 20 to fix the support plate 20.

The embodiments shown and described above are only examples. Many details are often found in the art such as the other features of a testing apparatus. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A testing apparatus comprising:
a test base;
a support plate configured for supporting a device located on the test base; and
a testing module located on the test base configured for testing the device;
wherein the support plate is detachably coupled with the test base.

2. The testing apparatus of claim 1, wherein the test base has a plurality of location parts, and the support plate has a plurality of location holes corresponding to the location parts, the location holes of the support plate receives the location parts of the test base to detachably couple the test base and the support plate.

3. The testing apparatus of claim 2, wherein a height of each location part is less than a depth of each location hole.

4. The testing apparatus of claim 2, wherein a height of each location part equals a depth of each location hole.

5. The testing apparatus of claim 2, wherein the location parts have a plurality of first location parts and a plurality of second location parts, the first location parts are aligned and located at a side of the test base along a longitudinal direction of the test base, and the second location parts are aligned and located at an opposite side of the test base along the longitudinal direction of the test base.

6. The testing apparatus of claim 5, wherein a distance between each two adjacent first location parts is less than a distance between each two adjacent second location parts.

7. The testing apparatus of claim 5, wherein the location parts have two first location parts and two second location parts.

8. The testing apparatus of claim 5, wherein the location parts are cylindrical.

9. The testing apparatus of claim 2, wherein the location holes extend through the support plate from a lower face to an upper face of the support plate.

10. The testing apparatus of claim 2, wherein the test base has a plurality of receiving cavities arranged in an upper face of the test base, a plurality of fixing parts are provided to be received in the receiving cavities to locate the support plate.

11. The testing apparatus of claim 10, wherein a height of the fixing part is higher than a depth of the receiving cavity.

12. The testing apparatus of claim 11, wherein an end of the fixing part is exposed out of the receiving cavity to abut peripheral sides of the support plate.

13. The testing apparatus of claim 10, wherein the fixing parts are made of elastic materials.

14. A testing apparatus comprising:
a test base;
a support plate configured for supporting a device located on the test base; and
a testing module located on the test base configured for testing the device;
wherein the test base has a plurality of receiving cavities arranged in an upper face of the test base, a plurality of fixing parts are provided to be received in the receiving cavities to locate the support plate.

15. The testing apparatus of claim 14, wherein a height of the fixing part is higher than a depth of the receiving cavity.

16. The testing apparatus of claim 14, wherein an end of the fixing part is exposed out of the receiving cavity to abut peripheral sides of the support plate.

17. The testing apparatus of claim 14, wherein the fixing part are made of elastic materials.
